(19) United States
(12) Patent Application Publication
(10) Pub. No.: US 2022/0100109 A1
(43) Pub. Date: Mar. 31, 2022

(54) APPARATUS FOR AND METHOD OF SIMULTANEOUSLY ACQUIRING PARALLEL ALIGNMENT MARKS

(71) Applicants: ASML Holding N.V., Veldhoven (NL); ASML Netherlands B.V., Veldhoven (NL)

(72) Inventors: Tamer Mohamed Tawfik Ahmed Mohamed ELAZHARY, New Canaan, CT (US); Franciscus BIJNEN, Valkenswaard (NL); Alessandro POLO, Arendonk (BE); Kirill Urievich SOBOLEV, Brookfield, CT (US); Simon Reinald HUISMAN, Eindhoven (NL); Justin Lloyd KREUZER, Trumbull, CT (US)

(73) Assignees: ASML Holding N.V., Veldhoven (NL); ASML Netherlands B.V., Veldhoven (NL)

(21) Appl. No.: 17/415,682

(22) PCT Filed: Dec. 12, 2019
(86) PCT No.: PCT/EP2019/084853

§ 371 Date: Jun. 17, 2021

Related U.S. Application Data
(60) Provisional application No. 62/782,715, filed on Dec. 20, 2018.

(51) Int. Cl. G03F 9/00; G02B 26/08

(52) U.S. Cl. CPC G03F 9/7069; G03F 9/7088; G02B 26/0816

(57) ABSTRACT

An apparatus for and method of determining the alignment of a substrate in which a multiple alignment marks are simultaneously illuminated with spatially coherent radiation and the light from the illuminated marks is collected in parallel to obtain information on the positions of the marks and distortions within the marks.

### CROSS-REFERENCE TO RELATED APPLICATIONS

This application claims priority of U.S. Provisional Patent Application No. 62/782,715, which was filed on Dec. 20, 2018 and which is incorporated herein in its entirety by reference.

### FIELD

The present disclosure relates to the manufacture of devices using lithographic techniques. Specifically, the present disclosure relates to devices for detecting alignment marks to characterize and control semiconductor photolithographic processes.

### BACKGROUND

A lithographic apparatus can be used, for example, in the manufacture of integrated circuits (ICs). For that application, a patterning device, which is alternatively referred to as a mask or a reticle, may be used to transfer a circuit pattern onto a target portion (e.g., comprising part of, one, or several dies) on a substrate (e.g., a silicon wafer). Transfer of the pattern is typically accomplished by imaging onto a layer of radiation-sensitive material (resist) provided on the substrate. In general, a single substrate will contain a network of adjacent target portions that are successively patterned.

Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning” direction) while synchronously scanning the substrate parallel or anti-parallel to this direction. It is also possible to transfer the pattern from the patterning device to the substrate by imprinting the pattern onto the substrate.

In order to control the lithographic process to place device features accurately on the substrate, one or more alignment marks are generally provided on, for example, the substrate or a substrate support, and the lithographic apparatus includes one or more alignment sensors by which the position of the mark or marks may be measured accurately. The alignment sensor may be effectively a position measuring apparatus. Different types of marks and different types of alignment sensors are known. Measurement of the relative positions of several alignment marks within the field can correct for process-induced wafer errors. Alignment error variation within the field can be used to fit a model to correct for error within the field.

Alignment involves placing the wafer/stage in a position such that the wafer/stage marks can be illuminated by a spatially coherent light source such as a HeNe laser. The beam interacts with the alignment mark and the resulting reflected diffraction pattern goes back through the lens. The mark pattern is reconstructed from the +/−first order components of the diffraction pattern (the zero order is returned to the laser, higher orders are blocked). The electric and magnetic fields result in a sinusoidal field image.

The wafer alignment sensor measures the location of the wafer on the wafer stage and maps the deformations of the wafer. This information is used in controlling the exposure settings to create the best conditions for optimal overlay performance With the ever-growing demand for increased wafer production, only about 3 seconds are available for the alignment sensor to measure up to about 40 alignment marks, without sacrificing wafer throughput. However, the more marks one can measure, the better one can correct for wafer deformations.

In addition, there is a benefit of aligning on smaller marks, preferably the same marks that are used for overlay metrology such as sub-micron-level diffraction based overlay marks. Smaller marks not only occupy less space on the wafer; they also would enable intra-field deformation corrections and remove overlay penalties caused by a mark-to-product offsets.

Lithographic apparatus are known to use multiple alignment systems to align the substrate with respect to the lithographic apparatus. The data can be obtained, for example, with any type of alignment sensor, for example a SMASH (SMart Alignment Sensor Hybrid) sensor, as described for example in U.S. Pat. No. 6,961,116, issued Nov. 1, 2005 and titled “Lithographic Apparatus, Device Manufacturing Method, and Device Manufactured Thereby,” which is hereby incorporated by reference herein in its entirety, that employs a self-referencing interferometer with a single detector and four different wavelengths, and extracts the alignment signal in software, or ATHENA (Advanced Technology using High order ENhancement of Alignment), as described for example in U.S. Pat. No. 6,297,876, issued Oct. 2, 2001 and titled “Lithographic Projection Apparatus with an Alignment System for Aligning Substrate on Mask,” which is hereby incorporated by reference in its entirety, which directs each of seven diffraction orders to a dedicated detector.

Existing alignment systems and techniques are subject to certain limitations. For example, they are generally incapable of measuring distortions within the alignment mark field, i.e., intra-field distortion. They also do not support finer alignment grating pitches, for example, grating pitches less than about 1 um.

Also, it is desirable to enable the use of a larger number of alignment marks because the use of a greater number of alignment marks offers the possibility of greater alignment precision. Current alignment sensors, however, typically can measure only one position of one alignment mark at a time. Therefore trying to measure the position of many marks using current alignment sensor technology would result in significant time and throughput penalties. It is thus desirable to have a sensor that can be used in arrangements that measure multiple alignment marks simultaneously.

There is thus a need for an alignment sensor capable of measuring multiple alignment marks simultaneously without affecting wafer throughput.

### SUMMARY

The following presents a simplified summary of one or more embodiments in order to provide a basic understanding of the embodiments. This summary is not an extensive overview of all contemplated embodiments, and is not intended to identify key or critical elements of all embodiments nor delineate the scope of any or all embodiments. Its sole purpose is to present some concepts of one or more embodiments in a simplified form as a prelude to the more detailed description that is presented later.

According to one aspect of an embodiment there is disclosed an apparatus for, and method of, detecting multiple alignment marks in parallel, that is, at substantially the same time. This entails illuminating the marks simultaneously and also collecting light that has interacted with the marks in parallel and conveying it to a plurality of detectors simultaneously. This is realized according to aspects of embodiments disclosed herein by using simultaneous illumination arrangements including, for example, optical fibers or a multimode interference device, to illuminate multiple marks at the same time. It is also realized according to aspects of embodiments disclosed herein by using arrangements to collect the light and directed to the detectors in parallel. These arrangements include, for example, arrangements having an Offner relay or arrangements using cylindrical lens in a scanner-type optical arrangement. It is also realized according to aspects of embodiments disclosed herein by using a linear array of sensors.

Further embodiments, features, and advantages of the present invention, as well as the structure and operation of the various embodiments are described in detail below with reference to accompanying drawings.

### BRIEF DESCRIPTION OF THE DRAWING

The accompanying drawings, which are incorporated herein and form part of the specification, illustrate the methods and systems of embodiments of the invention by way of example, and not by way of limitation. Together with the detailed description, the drawings further serve to explain the principles of and to enable a person skilled in the relevant art(s) to make and use the methods and systems presented herein. In the drawings, like reference numbers indicate identical or functionally similar elements.

FIG. 1 is a diagram of a lithographic apparatus according to one aspect of an embodiment.

FIG. 2A is a diagram of an arrangement using optical fibers for simultaneously illuminating multiple alignment marks according to an aspect of an embodiment.

FIG. 2B is a diagram of an arrangement using a multimode interference device for simultaneously illuminating multiple alignment marks according to an aspect of an embodiment.

FIG. 3 is a diagram of an arrangement for using two optical fibers to scan a segment of an array of alignment marks according to an aspect of an embodiment.

FIG. 4A is a diagram of a system for collecting radiation in parallel from an array of alignment marks according to an aspect of an embodiment using on-axis illumination.

FIG. 4B is a diagram of a system for collecting radiation in parallel from an array of alignment marks according to an aspect of an embodiment using off-axis illumination.

FIG. 5 is a diagram showing a possible position of a detector array in the embodiments of FIGS. 4A and 4B.

FIG. 6 is a diagram of another system for collecting radiation in parallel from an array of alignment marks according to an aspect of an embodiment.

FIG. 7 is a diagram of another system for collecting radiation in parallel from an array of alignment marks according to an aspect of an embodiment.

Further features and advantages of the invention, as well as the structure and operation of various embodiments of the invention, are described in detail below with reference to the accompanying drawings. It is noted that the invention is not limited to the specific embodiments described herein. Such embodiments are presented herein for illustrative purposes only. Additional embodiments will be apparent to persons skilled in the relevant art based on the teachings contained herein.

### DETAILED DESCRIPTION

Various embodiments are now described with reference to the drawings, wherein like reference numerals are used to refer to like elements throughout. In the following description, for purposes of explanation, numerous specific details are set forth in order to promote a thorough understanding of one or more embodiments. It may be evident in some or all instances, however, that any embodiment described below can be practiced without adopting the specific design details described below. In other instances, well-known structures and devices are shown in block diagram form in order to facilitate description of one or more embodiments. The following presents a simplified summary of one or more embodiments in order to provide a basic understanding of the embodiments. This summary is not an extensive overview of all contemplated embodiments, and is not intended to identify key or critical elements of all embodiments nor delineate the scope of any or all embodiments.

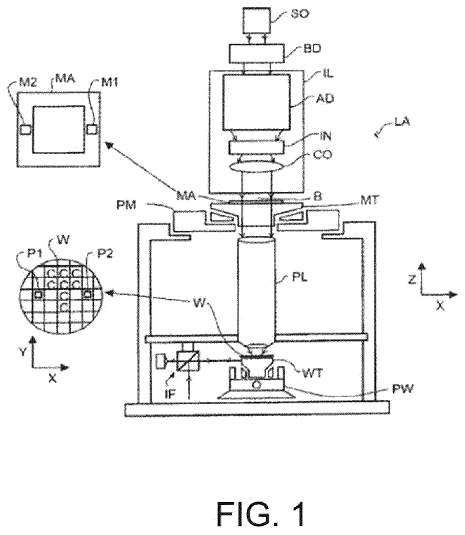

FIG. 1 schematically depicts a lithographic apparatus. The apparatus comprises an illumination system (illuminator) IL configured to condition a radiation beam B (e.g., UV radiation or other suitable radiation), a support structure (e.g., a mask table) MT constructed to support a patterning device (e.g., a mask) MA and connected to a first positioner PM configured to accurately position the patterning device in accordance with certain parameters, a substrate table (e.g., a wafer table) WT constructed to hold a substrate (e.g., a resist-coated wafer) W and connected to a second positioner PW configured to accurately position the substrate in accordance with certain parameters, and a projection system (e.g., a refractive projection lens system) PL configured to project a pattern imparted to the radiation beam B by patterning device MA onto a target portion C (e.g., comprising one or more dies) of the substrate W.

The illumination system may include various types of optical components, such as refractive, reflective, electromagnetic, electrostatic or other types of optical components, or any combination thereof, for directing, shaping, or controlling radiation.

The support structure supports, i.e., bears the weight of, the patterning device. It holds the patterning device in a manner that depends on the orientation of the patterning device, the design of the lithographic apparatus, and other conditions, such as for example whether or not the patterning device is held in a vacuum environment. The support structure can use mechanical, vacuum, electrostatic or other clamping techniques to hold the patterning device. The support structure may be a frame or a table, for example, which may be fixed or movable as required. The support structure may ensure that the patterning device is at a desired position, for example with respect to the projection system. Any use of the terms “reticle” or “mask” herein may be considered synonymous with the more general term “patterning device.”

The term “patterning device” used herein should be broadly interpreted as referring to any device that can be used to impart a radiation beam with a pattern in its cross-section such as to create a pattern in a target portion of the substrate. It should be noted that the pattern imparted to the radiation beam may not exactly correspond to the desired pattern in the target portion of the substrate, for example if the pattern includes phase-shifting features or so-called assist features. Generally, the pattern imparted to the radiation beam will correspond to a particular functional layer in a device being created in the target portion, such as an integrated circuit.

The patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam, which is reflected by the mirror matrix.

The term “projection system” used herein should be broadly interpreted as encompassing any type of projection system, including refractive, reflective, catadioptric, electromagnetic, and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

As here depicted, the apparatus is of a transmissive type (e.g., employing a transmissive mask). Alternatively, the apparatus may be of a reflective type (e.g., employing a programmable mirror array or employing a reflective mask).

The lithographic apparatus may be of a type having two (dual stage) or more substrate tables (and/or two or more mask tables). In such “multiple stage” machines the additional tables may be used in parallel, or preparatory steps may be carried out on one or more tables while one or more other tables are being used for exposure.

The lithographic apparatus may also be of a type wherein at least a portion of the substrate may be covered by a liquid having a relatively high refractive index, e.g., water, so as to fill a space between the projection system and the substrate. An immersion liquid may also be applied to other spaces in the lithographic apparatus, for example, between the mask and the projection system Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

Referring again to FIG. 1, the illuminator IL receives a radiation beam from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD comprising, for example, suitable directing mirrors and/or a beam expander. In other cases the source may be an integral part of the lithographic apparatus, for example when the source is a mercury lamp. The source SO and the illuminator IL, together with the beam delivery system BD if required, may be referred to as a radiation system.

The illuminator IL may comprise an adjuster AD for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as an integrator IN and a condenser CO. The illuminator may be used to condition the radiation beam, to have a desired uniformity and intensity distribution in its cross-section.

The radiation beam B is incident on the patterning device (e.g., mask MA), which is held on the support structure (e.g., mask table MT), and is patterned by the patterning device. Having traversed the mask MA, the radiation beam B passes through the projection system PL, which focuses the beam onto a target portion C of the substrate W. With the aid of the second positioner PW and position sensor IF (e.g., an interferometric device, linear encoder, 2-D encoder or capacitive sensor), the substrate table WT can be moved accurately, e.g., so as to position different target portions C in the path of the radiation beam B. Similarly, the first positioner PM and another position sensor (which is not explicitly depicted in FIG. 1) can be used to accurately position the mask MA with respect to the path of the radiation beam B, e.g., after mechanical retrieval from a mask library, or during a scan. In general, movement of the mask table MT may be realized with the aid of a long-stroke module (coarse positioning) and a short-stroke module (fine positioning), which form part of the first positioner PM. Similarly, movement of the substrate table WT may be realized using a long-stroke module and a short-stroke module, which form part of the second positioner PW. In the case of a stepper (as opposed to a scanner) the mask table MT may be connected to a short-stroke actuator only, or may be fixed. Mask MA and substrate W may be aligned using mask alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the mask MA, the mask alignment marks may be located between the dies. The wafer may also include additional marks such as, for example, marks that are sensitive to variations in a chemical mechanical planarization (CMP) process used as a step in wafer fabrication.

The target P1 and/or P2 on substrate W may be, for example, (a) a resist layer grating, which is printed such that after development, the bars are formed of solid resist lines, or (b) a product layer grating, or (c) a composite grating stack in an overlay target structure comprising a resist grating overlaid or interleaved on a product layer grating. The bars may alternatively be etched into the substrate.

A disadvantage of the known alignment systems is that they typically can measure only one alignment mark at a time. There are, however, potential advantages to being able to measure multiple alignment marks simultaneously. A system for measuring multiple alignment marks simultaneously involves both simultaneously illuminating the marks and simultaneously gathering the radiation illuminating the marks after it has been reflected by the marks.

As regards illumination, parallel marks can be measured, for instance, by illuminating multiple parallel marks laying on a scribe line. This can be achieved, for example, by using a fiber array or a multimode interference device. See, regarding the latter, L. B. Soldana et al., Optical Multi-Mode Interference Devices Based on Self-Imaging: Principles and Applications, Journal of Lightwave Technology, Volume 13, Issue 4, pp. 615-627 (April 1995) the entirety of which is hereby incorporated by reference herein.

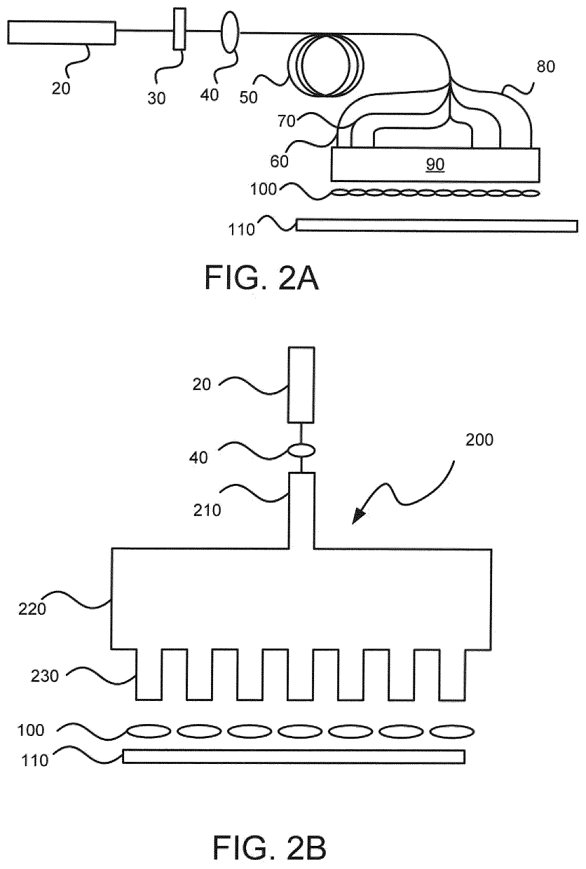

FIG. 2A shows an arrangement in which a light source 20 is directed to a 2D fiber bundle 50 through a spatial light modulator 30 and a coupler 40 to enable selective fiber illumination. As mentioned, light source 20 may be a spatially coherent light source such as a HeNe laser. The fiber bundle 50 is reformatted to a 1-D fiber bundle comprising a first fiber 60, a second fiber 70, and so on up to an nth fiber 80 by a fiber positioner 90. The light from each fiber is focused on a respective one of the alignment marks 110 through a respective lens of a micro-lens array 100.

FIG. 2B shows an arrangement in which a multimode interference (MMI) device 200 is used to illuminate the alignment marks 110. The beam from the source 20 is coupled by a coupler 40 into a single mode channel 210 of the MMI 200 that expands into a broad, multimode section 220 of the MMI 200. The many modes of the multimode section 220 propagate at different speeds with their interference giving rise to a cross-sectional intensity distribution. Access guides 230 placed at the end of the multimode section 220 carry away the concentrated optical energy which is coupled to the alignment marks 110 through a micro-lens array 100. An MMI is one example of an integrated optical device that may be used. Other integrated optical devices such as 1×N directional couplers may also be used.

The above arrangements are particularly advantageous when the alignment marks are in the scribe lane (i.e., printed on a straight line). In principle, the full wafer diameter (for example, 300 mm) can be covered by the illumination system giving the opportunity to illuminate all the marks printed in a scribe lane at once. In a different scenario the illumination could cover the full field extent (for example, 26 mm) to enable detection of parallel intra-field marks.

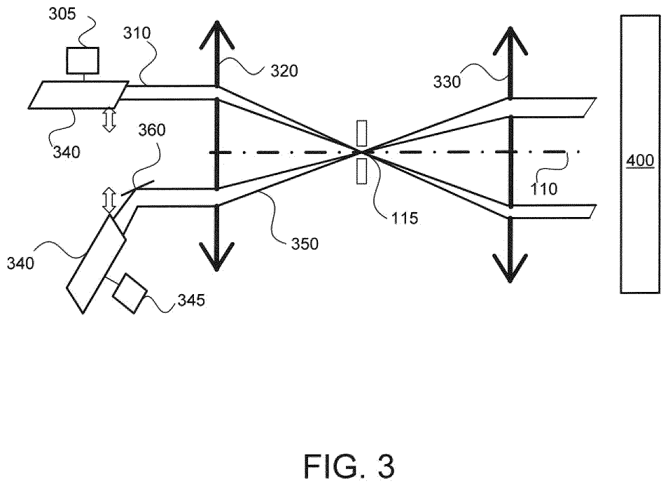

FIG. 3 shows a possible arrangement of a configurable illumination system for an intra-field distortion sensor. Shown in the figure is a first single mode fiber 300. The beam 310 from the single mode fiber 300 travels through a converging lens 320 and impinges on a segment 115 of the alignment mark array 110. The beam 310 is then reflected through a second converging lens 330 and impinges on an optical system 400. Similarly, the beam 350 from a second single mode fiber 340 impinges on a turning mirror 360 and passes through the converging lens 320. The beam 350 impinges on the segment 115, is reflected, and passes through second converging lens 330 after which it reaches the optical system 400. The light beams 310, 350 from the first single mode fiber 300 and the second single mode fiber 340, respectively are orthogonally polarized. The position of the single mode fibers 300 and 340 can be translated in a direction indicated by the arrows to scan the beams 310, 350 across at least part of the segment 115. The positions of the single mode fibers can be translated, for example, using devices for moving the single mode fibers such as micrometer screw drives 305 and 345, respectively. As configured the system can detect only one grating orientation at the time (e.g., x or y) for a scan direction. At least two sets of sensors (1 for X and 1 for Y) are required to record the full x mark and y mark positions.

In the arrangement just described, separate illumination channels are arranged to cover segments of the field of view. Translating the single mode fibers steers the beam within segments. For example, if the field is divided into five segments, a standalone illumination beam may be used as shown. The beam can be steered to any position within the field segment by translating the single mode fiber. As an example, if the single mode fiber beam waist at the fiber tip is 10 microns, the focal length ratio defines the beam waist at the alignment mark, which relates as well to the required translation resolution. For example, if a one micron translation resolution is required on the wafer, then in the single mode fiber plane this corresponds to a translation of 0.5 to 2 microns. The corresponding beam waist at the wafer is 5 to 20 microns.

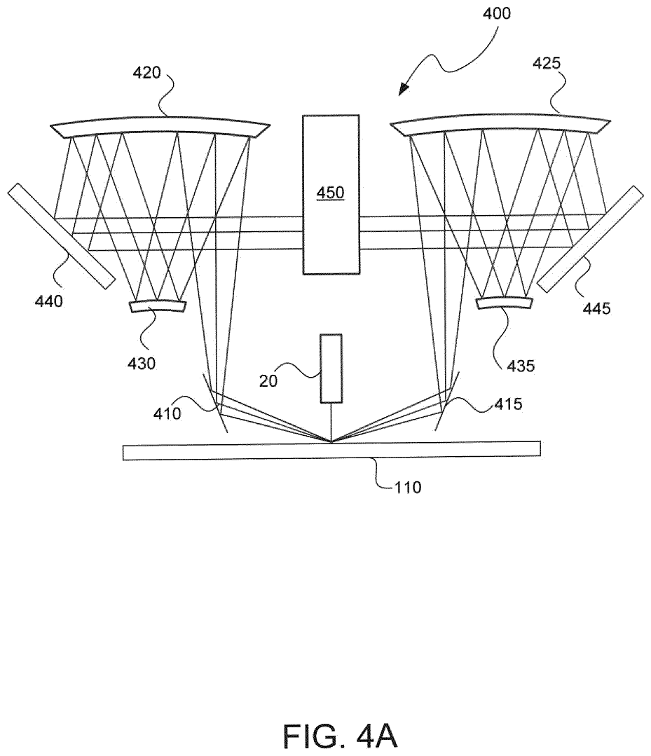

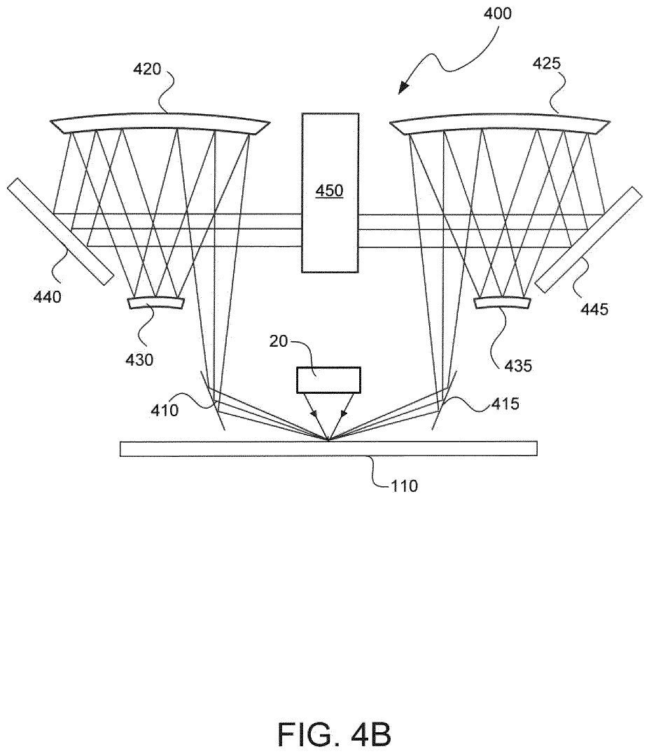

The foregoing describes various arrangements for illuminating the alignment marks The light scattered from the marks must then be collected by an optical system and relayed to detectors. The design of such an optical system has to take into account the very large field of view of the illumination system. One example of a suitable optical system includes an Offner optical relay system, which has the advantage of having limited aberrations for very large field of view. Such a system is shown in FIG. 4A. In FIG. 4A, an illumination source 20 illuminates an array 110 of alignment marks. In the embodiment shown, the illumination is on-axis, that is, the illumination propagates to strike the alignment marks substantially orthogonally. The optical system for gathering radiation from the alignment marks includes an Offner relay 400. Regarding the left hand side of the figure first, the light from the array 110 impinges on a turning mirror 410 and hits the concave surface of a curved mirror 420. The light from the curved mirror 420 then hits the convex surface of curved mirror 430. The curved mirror 430 then directs the light back onto the concave surface of the curved mirror 420 which in turn directs the light to a turning mirror 440. Turning mirror 440 directs the light to a detector array 450. The arrangement of the right hand side of the figure is mirror symmetric to that just described and functions in the same manner.

As mentioned, the arrangement in FIG. 4A uses an on-axis illumination system. It is also possible to illuminate the alignment mark using an off-axis illumination system such as shown in FIG. 4B. Here, the illumination strikes the alignment marks at an angle. The optical system for gathering radiation from the alignment marks can be essentially the same as that just described in which light from the array 110 impinges on a turning mirror 410 and hits the concave surface of a curved mirror 420. The light from the curved mirror 420 then hits the convex surface of curved mirror 430. The curved mirror 430 then directs the light back onto the concave surface of the curved mirror 420 which in turn directs the light to a turning mirror 440. Turning mirror 440 directs the light to a detector array 450. The arrangement of the right hand side of the figure is mirror symmetric to that just described and functions in the same manner Off-axis illumination offers the potential for detection of smaller grating pitches. In addition to the example shown, it will be apparent to one of ordinary skill in the art that other off-axis illumination configurations may be used.

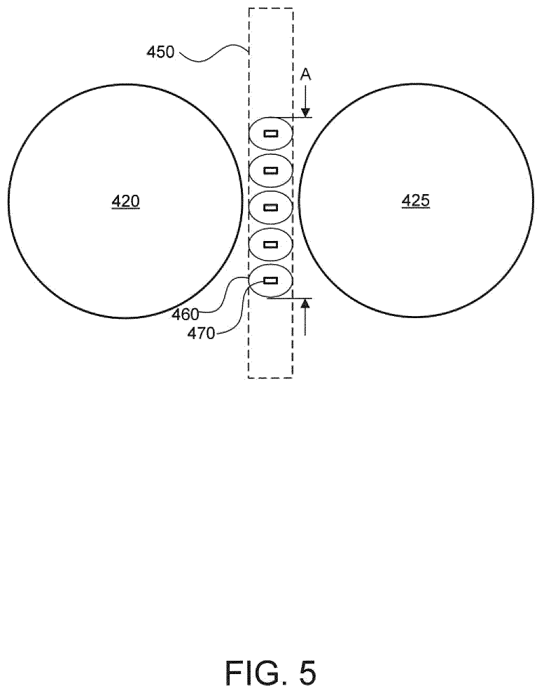

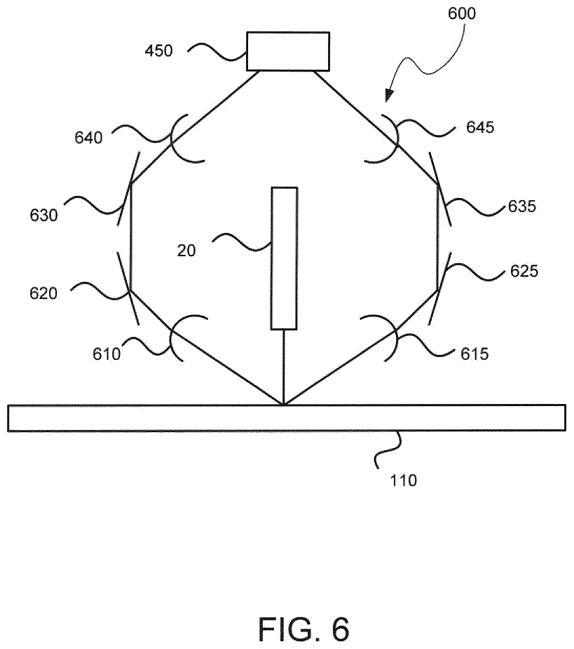

Thus the optical field is collected by a set of lenses and an array of photodetectors positioned in the conjugate plane with the sensor illumination spot as depicted in FIG. 5. As shown in the figure, the detector array 450 is placed in the conjugate plane between the Offner left mirror 420 and the Offner right mirror 425. The detector array 450 includes a linear array of lenses 460 with a photodiode 470 in the center of each. The micro-lenses may have, for example, a diameter on the order of 5 mm. This arrangement provides coverage for almost the entire field of view as indicated by the dimension designated with the letter A. This dimension is on the order of, for example, 26 mm. This arrangement provides flexibility for the placement marks within a limited range. The collected ±diffraction orders enter a interferometer to measure the alignment signals from the marks.

According to another aspect of an embodiment, the diffraction orders may be brought to focus on a CCD/CMOS 2D array in order to image the field on the wafer in a “flat scanner” type optical arrangement. Image processing techniques (for instance, edge detection, image registration, etc.) can be used to measure the position of the target on the wafer. Such an arrangement is shown in FIG. 6. As shown in the figure, a source 20 illuminates an array 110 of alignment marks. As shown, the illumination is on-axis but the illumination may alternatively be off-axis. The figure is two-dimensional and it will be understood that the arrangement depicted extends into the plane of the figure. Considering the left hand of the figure first, light from the array 110 is focused by a cylindrical lens 610 and then turned a first turning mirror 620 and a second turning mirror 630. The light is then focused again by a cylindrical mirror 640 and then impinges on detector array 450. The right hand side of figure is a mirror symmetric and operates in the same manner.

Thus, to focus the divergent beams of the orders of individual marks, cylindrical lens elements are positioned in the opposite direction of the detection direction. Optionally these cylindrical lens elements may be spaced at the wafer field or twice wafer field distances.

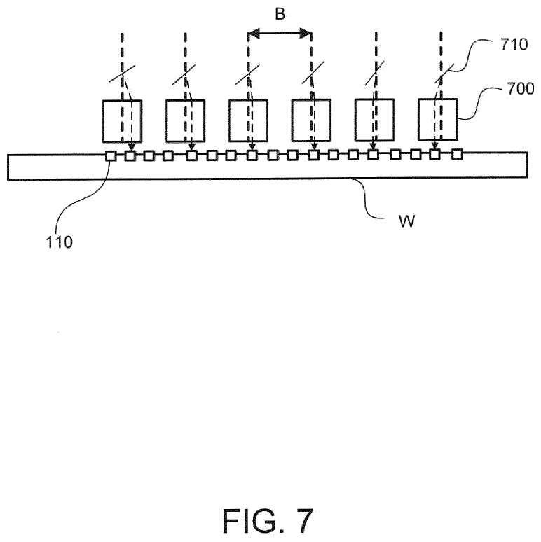

Another approach is shown in FIG. 7 in which a linear array of sensors 700 are placed at fixed distances along the array 110 of alignment marks. These sensors 700 are preferably equipped with a large field of view objective (for example on the order of about 3 mm) and a rotatable mirror 710 in the collimated space (close to the pupil plane). The angles of the mirrors 710 are adapted to the field and/or intra-field mark layout of the layer, such that each sensor 700 can simultaneously measure one mark. The figure shows a linear array of six sensors 700 but it is apparent a different number of sensors may be used. Thus, in this arrangement there are parallel sensors each with a respective tilting mirror that may be internal to each sensor.

The embodiments may further be described using the following clauses:

1. Apparatus for simultaneously detecting a plurality of parallel alignment marks of an alignment pattern, the apparatus comprising:

a light source for simultaneously generating a plurality of light beams, the plurality of light beams comprising a respective spatially coherent light beam each for illuminating a respective one of the alignment marks;

light collection optics arranged to simultaneously collect each light beam of the plurality of light beams after the light beam has interacted with a respective alignment mark; and

a plurality of detectors each respectively arranged to receive one of the plurality of light beams.

2. Apparatus of clause 1 wherein the light source comprises a plurality of single mode fibers.
3. Apparatus of clause 2 wherein the single mode fibers are movable and light from the single mode fibers is relayed to the alignment marks in such a manner that moving the single mode fibers causes light from the single mode fibers to scan a segment of the alignment marks.
4. Apparatus of clause 3 wherein each of the single mode fibers is mechanically coupled to a device for moving the single mode fiber.
5. Apparatus of clause 1 wherein the light source comprises an integrated optical device
6. Apparatus of clause 5 wherein the integrated optical device comprises a multimode interference device.
7. Apparatus of clause 5 wherein the integrated optical device comprises a 1×N directional coupler.
8. Apparatus of any one of clauses 1-7 wherein the light source provides on-axis illumination.
9. Apparatus of any one of clauses 1-7 wherein the light source provides on-axis illumination.
10. Apparatus of any one of clauses 1-7 wherein the light collection optics comprises an Offner relay.
11. Apparatus of any one of clauses 1-10 wherein the light collection optics comprises a plurality of cylindrical lenses.
12. Apparatus of any one of clauses 1-11 wherein the plurality of detectors comprises a plurality of detector elements arranged in a linear array adjacent and parallel to the parallel alignment marks, and wherein the light collection optics comprises a plurality of objective lenses, each of the plurality of detector elements having a respective one of the plurality of objective lenses.
13. Apparatus of clause 12 further comprising a plurality of turning mirrors, each of the turning mirrors being arranged to receive an incoming illumination light beam, the turning mirrors being adjustable so as to direct the incoming illumination light beam to a respective one of the alignment marks.
14. Apparatus for simultaneously illuminating a plurality of parallel alignment marks of an alignment pattern, the apparatus comprising:

a source of a spatially coherent radiation; and

an optical element arranged to receive the spatially coherent radiation and to simultaneously generate a plurality of light beams, the plurality of light beams comprising a respective spatially coherent light beam for each of the alignment marks.

15. Apparatus of clause 14 wherein the optical element comprises a plurality of single mode fibers.
16. Apparatus of clause 14 wherein the source comprises an integrated optical device.
17. Apparatus of clause 16 wherein the integrated optical device comprises a multimode interference device.
18. Apparatus of clause 16 wherein the integrated optical device comprises a 1×N directional coupler.
19. Apparatus of any one of clauses 14-18 wherein the light source provides on-axis illumination.
20. Apparatus of any one of clauses 14-18 wherein the light source provides on-axis illumination.
21. A method of simultaneously detecting a plurality of parallel alignment marks of an alignment pattern, the method comprising the steps of:

simultaneously generating a plurality of light beams, the plurality of light beams comprising a respective spatially coherent light beam for each of the alignment marks;

collecting in parallel each light beam of the plurality of light beams after the light beam has interacted with a respective alignment mark; and

conveying in parallel each collected light beam to a respective one of a plurality of detectors.

22. A method of clause 21 wherein the step of simultaneously generating a plurality of light beams comprises using a plurality of single mode fibers.
23. A method of clause 22 wherein the step of simultaneously generating a plurality of light beams comprises moving single mode fibers to cause light from the single mode fibers to scan a segment of the alignment marks.
24. A method of clause 21 wherein the step of simultaneously generating a plurality of light beams comprises using an integrated optical device.
25. A method of clause 24 wherein the step of simultaneously generating a plurality of light beams comprises using a multimode interference device.
26. A method of clause 24 wherein the step of simultaneously generating a plurality of light beams comprises using an N×1 directional coupler.
27. A method of any one of clauses 21-26 wherein the step of simultaneously generating a plurality of light beams comprises generating the plurality of light beams on axis.
28. A method of any one of clauses 21-26 wherein the step of simultaneously generating a plurality of light beams comprises generating the plurality of light beams off axis.
29. A method of any one of clauses 21-28 wherein the step of collecting in parallel each light beam of the plurality of light beams after the light beam has interacted with a respective alignment mark comprises use of an Offner relay.
30. A method of any one of clauses 21-28 wherein the step of collecting in parallel each light beam of the plurality of light beams after the light beam has interacted with a respective alignment mark comprises use of a plurality of cylindrical lenses.
31. A method of any one of clauses 21-30 wherein the step of simultaneously generating a plurality of light beams comprises causing the each of the light beams to fall on a respective one of a plurality of adjustable mirrors.
32. A method of any one of clauses 21-31 wherein the step of conveying in parallel each collected light beam to a respective one of a plurality of detectors comprises conveying the light to a detector in a linear array adjacent and parallel to the parallel alignment marks.

Described above are arrangements in which an illumination system is provided to illuminate multiple marks at the same time and a detection system to measure multiple marks at the same time (in the scribe lane or intra-field). The marks may be diffraction based and the image of the mark is generated from the first+/−diffraction orders. This it is possible to measure multiple alignment marks within a field simultaneously. It also is possible to detect and correct for intra-field distortion. It also permits detection of small alignment marks which, among other benefits, increases the area on wafer available for product.

Although specific reference may have been made above to the use of embodiments of the invention in the context of optical lithography, it will be appreciated that the invention may be used in other applications, for example imprint lithography, and where the context allows, is not limited to optical lithography. In imprint lithography a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

The term “lens”, where the context allows, may refer to any one or combination of various types of optical components, including refractive, reflective, electromagnetic and electrostatic optical components.

The present invention has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

The breadth and scope of the present invention should not be limited by any of the above-described exemplary embodiments, but should be defined only in accordance with the following claims and their equivalents.

1.-20. (canceled)

21. An apparatus comprising:
a light source configured to simultaneously generating a plurality of light beams, the plurality of light beams comprising a respective spatially coherent light beam each for illuminating a respective one of a plurality of parallel alignment marks of an alignment pattern;
light collection optics arranged to simultaneously collect each light beam of the plurality of light beams after the light beam has interacted with the respective one of the alignment marks; and
a plurality of detectors each respectively arranged to receive one of the plurality of light beams.

22. The apparatus of claim 21, wherein the light source comprises single mode fibers.

23. The apparatus of claim 22, wherein:
the single mode fibers are movable, and
light from the single mode fibers is relayed to the alignment marks in such a manner that moving the single mode fibers causes light from the single mode fibers to scan a segment of the alignment marks.

24. The apparatus of claim 23, wherein each of the single mode fibers are mechanically coupled to a device for moving the single mode fiber.

25. The apparatus of claim 21, wherein the light source comprises an integrated optical device.

26. The apparatus of claim 25, wherein the integrated optical device comprises a multimode interference device.

27. The apparatus of claim 25, wherein the integrated optical device comprises a 1×N directional coupler.

28. The apparatus of claim 21, wherein the light source provides on-axis illumination.

29. The apparatus of claim 21, wherein the light source provides off-axis illumination.

30. The apparatus of claim 21, wherein the light collection optics comprises an Offner relay.

31. The apparatus of claim 21, wherein the light collection optics comprises a plurality of cylindrical lenses.

32. The apparatus of claim 21, wherein:
the plurality of detectors comprises a plurality of detector elements arranged in a linear array adjacent and parallel to the parallel alignment marks, and
the light collection optics comprises a plurality of objective lenses, each of the plurality of detector elements having a respective one of the plurality of objective lenses.

33. The apparatus of claim 32, further comprising a plurality of turning mirrors, each of the turning mirrors being arranged to receive an incoming illumination light beam, the turning mirrors being adjustable so as to direct the incoming illumination light beam to a respective one of the alignment marks.

34. An apparatus comprising:
a source of a spatially coherent radiation; and
an optical element arranged to receive the spatially coherent radiation and to simultaneously generate a plurality of light beams, the plurality of light beams comprising a respective spatially coherent light beam for each of a plurality of parallel alignment marks of an alignment patter.

35. The apparatus of claim 34, wherein the optical element comprises single mode fibers.

36. The apparatus of claim 34, wherein the source comprises an integrated optical device.

37. The apparatus of claim 36, wherein the integrated optical device comprises a multimode interference device.

38. The apparatus of claim 36, wherein the integrated optical device comprises a 1×N directional coupler.

39. The apparatus of claim 34, wherein the light source provides on-axis illumination.

40. The apparatus of claim 34, wherein the light source provides off-axis illumination.
